(19) United States
(12) Patent Application Publication
(10) Pub. No.: US 2018/0265350 A1
(43) Pub. Date: Sep. 20, 2018

(54) DEVICE AND SYSTEM FOR INTEGRATED SENSOR SYSTEM (ISS)

(71) Applicant: INVENSENSE, INC., San Jose, CA (US)

(72) Inventors: Stephen LLOYD, Los Altos, CA (US); James LIM, Saratoga, CA (US)

(21) Appl. No.: 15/982,818

(22) Filed: May 17, 2018

Related U.S. Application Data
(63) Continuation of application No. 14/201,729, filed on Mar. 7, 2014, now abandoned.
(60) Provisional application No. 61/791,331, filed on Mar. 15, 2013.

(51) Int. Cl. B81C 1/00

(52) U.S. Cl. CPC B81C 1/0023; H01L 2224/16225; H01L 2924/15184; H01L 2924/00012; H01L 2224/48145; H01L 2224/48227; H01L 2924/00014; H01L 2224/48091

(57) ABSTRACT

The present invention is directed toward a device and system having a sensor hub capable of receiving measurement outputs from a plurality of sensors and processing the measurements for output to other devices, from a single chip arrangement. The sensor hub provides for facilitating efficient communication among the sensors for improved high-level features, such as interpreting gestures or actions according to the context.

### CROSS-REFERENCE TO RELATED APPLICATIONS

This application is a continuation of, and claims priority to each of, U.S. patent application Ser. No. 14/201,729, filed Mar. 7, 2014, and entitled “DEVICE AND SYSTEM FOR INTEGRATED SENSOR SYSTEM (ISS),” which claims the benefit of U.S. Provisional Application No. 61/791,331, filed Mar. 15, 2013, and entitled “INTEGRATED SENSOR SYSTEM.” The entireties of the foregoing applications are hereby incorporated by reference herein.

### FIELD OF THE INVENTION

This present invention relates to integrated systems arranged to include microelectromechanical systems (MEMS) that provide for signal processing and more particularly for those systems that provide for the processing of signals from sensors and also provide for the outputting of information from the processed signals to other devices, applications and arrangements.

### BACKGROUND

Receiving measurement outputs from a plurality of sensors and processing the measurements for a user's requirements often involves complexity in understanding user needs, sensors to be integrated and in communication with multiple sourced devices, and complicated configuring of protocols between applications. Accordingly, what is needed is a device and system that is able to facilitate efficient communication among the sensors to be used for data acquisition which is also able to provide processing of the received data to meet user needs. Similarly, it is also desired that the capability to provide for interpreting complicated sensed actions.

Accordingly, the present invention addresses such a need and solution and is directed to such a need in overcoming the prior limitations in the field.

### SUMMARY

According to one or more embodiments of the present disclosure, a device having a sensor hub is capable of receiving measurement outputs from a plurality of sensors, where the plurality of sensors is formed on a first substrate and a portion of the sensor hub is coupled to the plurality of sensors and formed on a second substrate, is provided for. In another embodiment a second portion of the sensor hub is formed on a third substrate. Further, the sensor hub is capable of receiving measurement outputs from the plurality of sensors, and the sensor hub includes a plurality of processors coupled to the plurality of sensors to process the measurement outputs. Additionally, the first silicon substrate of the device is attached to the second silicon substrate of the device and the first silicon substrate is electrically connected to the second silicon substrate to form a first semiconductor chip, in one or more embodiments. In some embodiments, the third silicon substrate is formed on a second semiconductor chip, the first semiconductor chip and the second semiconductor chip are electrically connected and reside in single package.

According to other embodiments of the present disclosure, an integrated sensor system having a plurality of embedded sensors and a sensor hub, wherein the plurality of embedded sensors and the sensor hub are on a single chip, is provided for. Further, the sensor hub of the system comprises a plurality of processors coupled to the plurality of embedded sensors to process measurement outputs from the plurality of embedded sensors and external sensors and memory, in one or more embodiments.

According to other embodiments of the present disclosure, an integrated sensor system having a plurality of embedded sensor and a sensor hub, wherein the sensor hub comprises a plurality of processors coupled to the plurality of embedded sensors to process measurement outputs from the plurality of embedded sensors and external sensors and memory, is provided for. Further, the memory and the plurality of embedded sensors of the system are on a first chip and the processors are on a second chip, in one or more embodiments.

According to other embodiments of the present disclosure, an integrated sensor system having a plurality of sensors and a sensor hub coupled to the plurality of sensors is provided for. Additionally the sensor hub of the device receives measurement outputs from the plurality of sensors, and comprises a plurality of processors coupled to the plurality of sensors to process the measurement outputs. Further, the plurality of sensors and the sensor hub are on at least two substrates, wherein the at least two substrates are stacked and electrically connected to the each other to form a single semiconductor chip, in one or more embodiments.

According to other embodiments of the present disclosure, an integrated sensor system having a plurality of embedded sensors and a sensor hub, wherein the sensor hub comprises a plurality of processors coupled to the plurality of embedded sensors to process measurement outputs from the plurality of embedded sensors and external sensors and memory, is provided for. Further, a first portion of the plurality of embedded sensors are on a first chip and a second portion of the plurality of embedded sensors and the plurality of processors on a second chip, in one or more embodiments.

According to other embodiments of the present disclosure, an integrated sensor system having a plurality of embedded sensors and a sensor hub, wherein the sensor hub comprises a plurality of processors coupled to the plurality of embedded sensors to process measurement outputs from the plurality of embedded sensors and external sensors and memory, is provided for. Further, a portion of the plurality of embedded sensors, a portion of the plurality of processors are on a first chip and another portion of the plurality of embedded sensors and another portion of the plurality of processors are on a second chip, in one or more embodiments.

According to other embodiments of the present disclosure, an integrated sensor system having a plurality of embedded sensors and a sensor hub, wherein the sensor hub comprises a plurality of processors coupled to the plurality of embedded sensors to process measurement outputs from the plurality of embedded sensors and external sensors and memory, is provided for. Further, the memory and the plurality of processors are on are on a first chip and the plurality of embedded sensors are on a second chip, in one or more embodiments.

According to other embodiments of the present disclosure, an integrated sensor system having a plurality of sensors and a sensor hub coupled to the plurality of sensors, wherein the sensor hub receives measurement outputs from the plurality of sensors and the sensor hub comprises a plurality of processors coupled to the plurality of sensors to process the measurement outputs, is provided for. Further, the plurality of sensors and the sensor hub are on at least two substrates, wherein the at least two substrates are stacked and electrically connected to the each other to form a single semiconductor chip, in one or more embodiments.

Additional embodiments of the present disclosure provide for a device and system having a plurality of sensors and a sensor hub coupled to the plurality of sensors, for receiving outputs from the plurality of sensors to be implemented in computer programmable software and stored in computer readable media.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

FIG. 1 is an exemplary system diagram for the device and system herein having one or more embedded sensors and a sensor hub on a single chip, in accordance with one or more embodiments of the present invention.

FIG. 2A is an exemplary integrated sensor system (ISS) of the present invention having one or more embedded sensors in one or more MEMS chips and one or more CMOS chips with electronic circuits, in a single chip, in accordance with one or more embodiments of the present invention.

FIG. 2B is an exemplary integrated sensor system (ISS) of the present invention having one or more MEMS chips and one or more CMOS chips vertically stacked and bonded on a substrate, in accordance with one or more embodiments of the present invention.

FIG. 2C is an exemplary integrated sensor system (ISS) of the present invention having one or more MEMS chips and one or more CMOS chips vertically stacked and bonded on a substrate, in accordance with one or more embodiments of the present invention

FIG. 3 depicts a system diagram of the ISS in which the sensor hub comprises one or more analog to digital convertors, one or more processors, memory, a power management block and a controller block, in accordance with one or more embodiments of the present invention.

### DETAILED DESCRIPTION

The present invention relates to integrated systems arranged to include microelectromechanical systems (MEMS) that provide for signal processing and more particularly for those systems that provide for the processing of signals from sensors and also provide for the outputting of information from the processed signals to other devices, applications and arrangements. Further, the application relates to integrated sensor systems (ISSs) comprising one or more embedded sensors and a sensor hub arranged on a single chip, which can also receive inputs from external sensor sources and provide for facilitating efficient communication among the sensors for improved high-level features, such as interpreting gestures or actions according to the context.

The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiments shown, but is to be accorded the widest scope consistent with the principles and features described herein.

In the described embodiments, Micro-Electro-Mechanical Systems (MEMS) refers to a class of devices fabricated using semiconductor-like processes and exhibiting mechanical characteristics such as the ability to move or deform. MEMS often, but not always, interact with electrical signals. Silicon wafers containing MEMS structures are referred to as MEMS wafers. MEMS device may refer to a semiconductor device implemented as a micro-electro-mechanical system. A MEMS device includes mechanical elements and optionally includes electronics for sensing. MEMS devices include but not limited to gyroscopes, accelerometers, magnetometers, and pressure sensors. MEMS features refer to elements formed by MEMS fabrication process such as bump stop, damping hole, via, port, plate, proof mass, standoff, spring, seal ring, proof mass. MEMS structure may refer to any feature that may be part of a larger MEMS device. One or more MEMS features comprising moveable elements is a MEMS structure. Integrated Circuit (IC) substrate may refer to a silicon substrate with electrical circuits, typically CMOS circuits. A chip includes at least one substrate typically formed from a semiconductor material. A single chip may be formed from multiple substrates, where the substrates are mechanically bonded to preserve the functionality. Multiple chip includes at least 2 substrates, wherein the 2 substrates are electrically connected, but do not require mechanical bonding. A package provides electrical connection between the bond pads on the chip to a metal lead that can be soldered to a PCB. A package typically comprises a substrate and a cover.

In the described embodiments, “raw data” or “sensor data” refers to measurement outputs from the sensors which are not yet processed. “Motion data” refers to processed sensor data. Processing may include applying a sensor fusion algorithm or applying any other algorithm such as determining context, gestures, orientation, or confidence value. In the case of the sensor fusion algorithm, data from one or more sensors are combined to provide an orientation of the device. Processor data for example may include motion data plus audio data plus vision data (video, still frame) plus touch/temp data plus smell/taste data.

As used herein, integrated sensor systems (ISSs) comprise microelectromechanical systems (MEMS) and sensor subsystems for a user's application which combine multiple sensor sensing types and capabilities (position, force, pressure, discrete switching, acceleration, angular rate, level, etc.), where that application may be biological, chemical, electronic, medical, scientific and/or other sensing application. ISSs as used herein also are intended to provide improved sizing and physical structures which are oriented to become smaller with improved technological gains. Similarly, as used here, ISSs also have suitable biocompatibility, corrosion resistance, and electronic integration for applications in which they may be deployed.

In an embodiment of the invention, the first substrate is attached to the second substrate through wafer bonding, as described in commonly owned U.S. Pat. No. 7,104,129 (incorporated herein by reference) that simultaneously provides electrical connections and hermetically seals the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

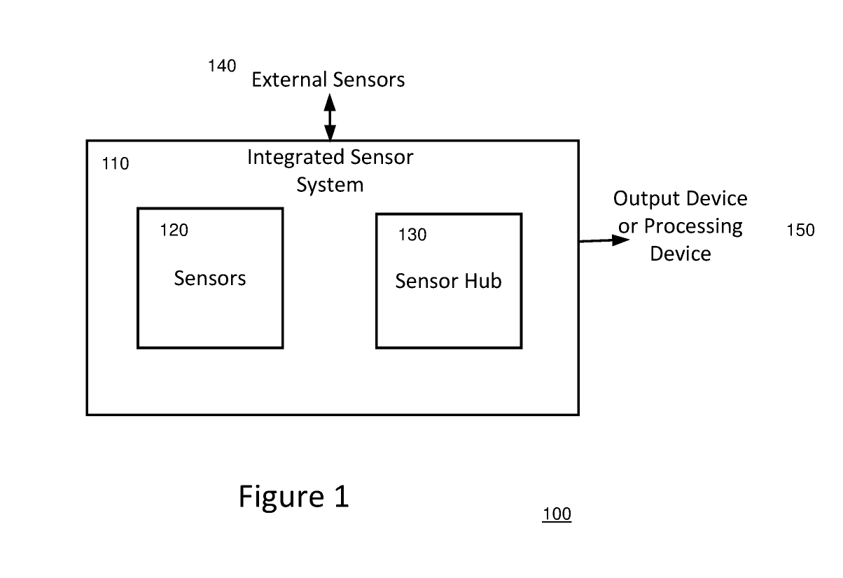

FIG. 1 is an exemplary system diagram 100 for the device and system 110 herein having one or more embedded sensors 120 and a sensor hub 130 on a single chip 100, in accordance with one or more embodiments of the present invention. In an embodiment, the ISS 110 is capable of communicating with external sensors 140 and also capable of outputting information, such as processed sensor data, to another device 150.

Operationally, the sensor hub 130 receives sensor data from sensors 120. The sensors 120 may include sensing devices, electronic circuits for converting analog signals to digital signals, and capable of determining sensed activities and information. These activities for example could include but are not limited to sleeping, waking up, walking, running, biking, participating in a sport, walking on stairs, driving, flying, training, exercising cooking, watching a television, reading, working at a computer, and eating.

Furthermore the sensors could be utilized for determining sensed locations. For example, these locations include but are not limited to a home, a workplace, a moving vehicle, indoor, outdoor, a meeting room, a store, a mall, a kitchen, a living room, and bedroom.

In such an embodiment signals from a global positioning system (GPS) or other wireless system that generates location data could be utilized. In addition the sensors could send data to a GPS or other wireless system that generates location data to aid in low power location and navigation.

Sensors may include those devices which are capable of gathering data and/or information involving measurements concerning an accelerometer, gyroscope, compass, pressure, microphone, humidity, temperature, gas, chemical, ambient light, proximity, touch, and tactile information, for example; however the present invention is not so limited. Sensors of the present invention are embedded sensors for those sensors on the chip and/or external to the ISS for sensed data external to the chip, in one or more embodiments. From FIG. 1, the ISS 110 processes signals from sensors 120, 140 and outputs 150 to any other output device or to another device for further processing. For example, in an embodiment, the output device is one or more of an application processor, memory, an audio output device, a haptic sensor and a LED.

In another embodiment, the sensors are a MEMS sensor or a solid state sensor, though the sensors of the device and system may be any type of sensor. For instance, it is envisioned that the present invention may use data sensed from sensors including but not limited to a 3-axis accelerometer, 3-axis gyroscope, 3-axis magnetometer, pressure sensor, microphone, chemical sensor, gas sensor, humidity sensor, image sensor, ambient light, proximity, touch, and audio sensors, etc.

In a further embodiment, a gyroscope of the present invention includes the gyroscope disclosed and described in commonly-owned U.S. Pat. No. 6,892,575, entitled “X-Y Axis Dual-Mass Tuning Fork Gyroscope with Vertically Integrated Electronics and Wafer-Scale Hermetic Packaging”, which is incorporated herein by reference. In another embodiment, the gyroscope of the present invention is a gyroscope disclosed and described in the commonly-owned U.S. patent application Ser. No. 13/235,296, entitled “Micromachined Gyroscope Including a Guided Mass System”, also incorporated herein by reference. In yet a further embodiment, the pressure sensor of the present invention is a pressure sensor as disclosed and described in the commonly-owned U.S. patent application Ser. No. 13/536,798, entitled “Hermetically Sealed MEMS Device with a Portion Exposed to the Environment with Vertically Integrated Electronics,” incorporated herein by reference.

In a further embodiment of the present invention includes the sensors are formed on a MEMS substrate, the electronic circuits are formed on a CMOS substrate, the CMOS and the MEMS substrates are vertically stacked and attached is disclosed and described in commonly-owned U.S. Pat. No. 8,250,921, entitled “Integrated Motion Processing Unit (MPU) With MEMS Inertial Sensing And Embedded Digital Electronics”

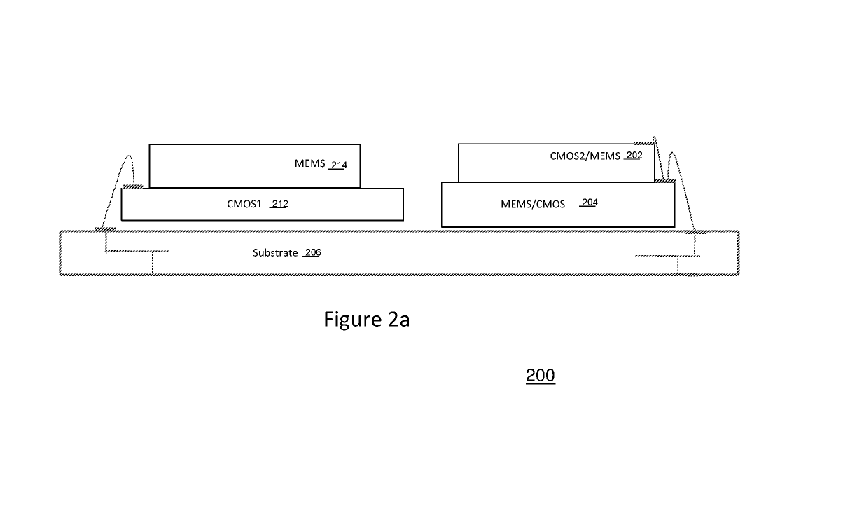

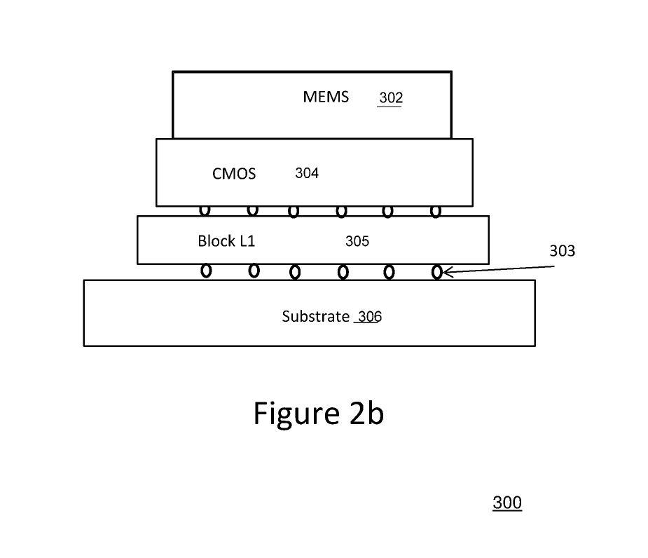

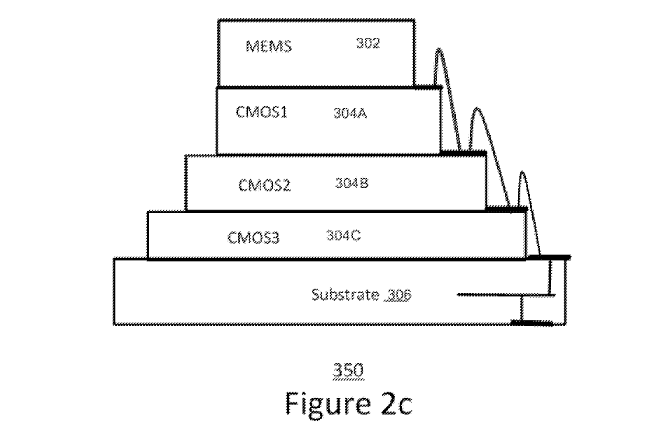

FIG. 2A is an exemplary integrated sensor system (ISS) of the present invention having one or more embedded sensors in one or more MEMS chip 214 and one or more CMOS chip 212 with electronic circuits, attached to a substrate 206 to form a single chip 200, in accordance with one or more embodiments of the present invention. In the described embodiments, the electronic circuits may include circuitry for sensing signals from sensors, processing the sensed signals and converting to digital signals. In an embodiment, FIG. 2a also provides for an ISS of the present invention having a first arrangement of a MEMS 214 arranged with a CMOS 212 vertically, and a second arrangement of a chip 202 vertically stacked with a chip 204, where the first and second arrangement are side-by-side on a substrate 206. Chip 202 and chip 204 can be any combination of CMOS and MEMS. In another embodiment, chip 202 may not be present. Yet, in another embodiment, multiple chips such as 202 or 204 may be stacked. In some embodiments, CMOS chip may also include memory.

FIG. 2B is an exemplary integrated sensor system (ISS) 300 of the present invention having one or more MEMS chip 302 and one or more CMOS chip 304 vertically stacked and bonded 303 on a substrate 306, in accordance with one or more embodiments of the present invention. In an arrangement, the combined MEMS and CMOS chips are bonded or connected by solder balls to block 305 and then bonded to the substrate 306. In an embodiment block 305 could be any of or any combination of electronics, sensors or solid state devices such as batteries.

FIG. 2C is an exemplary integrated sensor system (ISS) 350 of the present invention having one MEMS chip 302 and a plurality of CMOS chips 304A-304C are vertically stacked and CMOS chip 304A is wire bonded to CMOS chip 304B which is wire bonded to CMOS chip 304C. The CMOS chip 304C in turn is wire bonded to a substrate 306, in accordance with one or more embodiments of the present invention. In an embodiment the CMOS chips 304A, 304B and 304C could contain any of or any combination of electronic circuits.

In one embodiment, this present invention relates to integrated systems arranged to include microelectromechanical systems (MEMS) that provide for signal processing and more particularly for those systems that provide for the processing of signals from sensors and also provide for the outputting of information from the processed signals to other devices, applications and arrangements. Further, the application relates to integrated sensor systems (ISSs) comprising one or more embedded sensors and a sensor hub arranged on a single chip, which can also receive inputs from external sensor sources and provide for facilitating efficient communication among the sensors for improved high-level features, such as interpreting gestures or actions according to the context. The present invention provides for an ISS implemented in a single chip that can be mounted onto a surface of a printed circuit board (PCB). In another embodiment, the ISS of the present invention comprises one or more MEMS chip having one or more sensors attached to one or more CMOS chips with electronic circuitry. In a further embodiment, one or more MEMS chips and one or more CMOS chips are vertically stacked and bonded. In yet another embodiment, an ISS of the present invention provides for having more than one MEMS and more than one CMOS chips arranged and placed side-by-side.

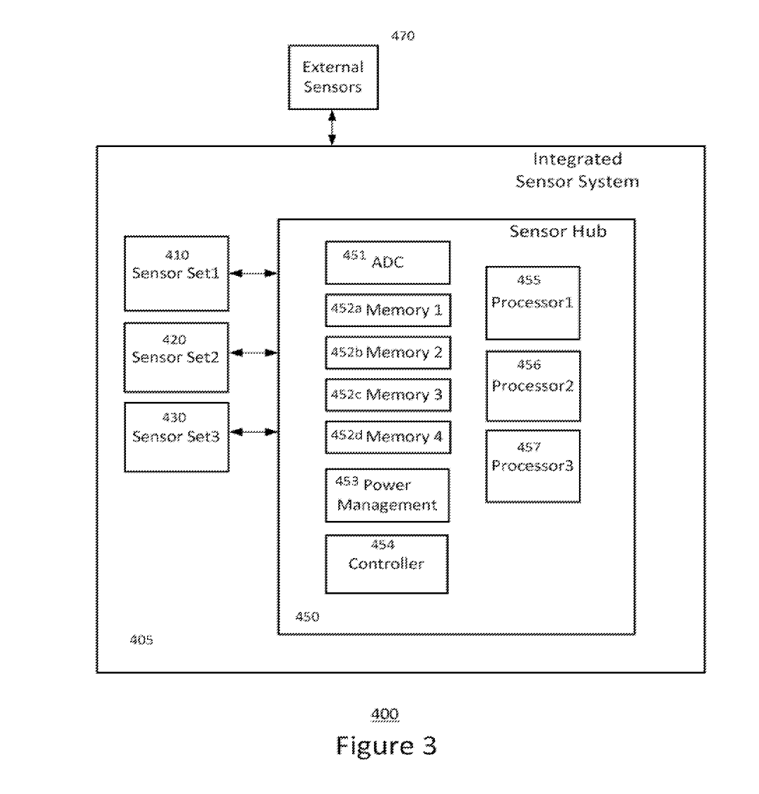

FIG. 3 depicts a system diagram 400 of the ISS 405 in which the sensor hub 450 comprises one or more analog to digital convertors 451, one or more processors (455-457), memory 452, a power management block 453 and a controller block 454, in accordance with one or more embodiments of the present invention. In an embodiment, the sensor hub 450 comprises one or more analog to digital convertors, one or more processors, memory, one or more power management blocks and one or more controller blocks. For example, the one or more processors 455-457 include but are not limited to any and any combination of an audio processor, an image processor, a motion processor, a touch processor, a location processor, a wireless processor, a radio processor, a graphics processor, a power management processor, an environmental processor, an application processor (AP), and a microcontroller unit (MCU). Any of the one or more processors 455-457 or external sensors 470 can provide one or more interrupts to an external device, any of the embedded or external sensors, or any processor or the like based upon the sensor inputs. The interrupt signal can performs any of or any combination of wake-up a processor and/or sensor from a sleep state, initiate transaction between memory and sensor, initiate transaction between memory and processor, initiate transfer of data between memory and external device. In addition, the sensor hub may include in some embodiments a real-time clock (RTC), a system clock oscillator or any other type of clock circuitry. In an embodiment, resonators for the clocks can be implemented with MEM structure. In so doing external crystal resonators are not required thereby saving cost, reducing power requirements and reducing the overall size of the device.

Embodiments of the sensor hub described herein can take the form of an entirely hardware implementation, an entirely software implementation, or an implementation containing both hardware and software elements. Embodiments may be implemented in software, which includes, but is not limited to, application software, firmware, resident software, microcode, etc.

The steps described herein may be implemented using any suitable controller or processor, and software application, which may be stored on any suitable storage location or computer-readable medium. The software application provides instructions that enable the processor to cause the receiver to perform the functions described herein.

Furthermore, embodiments may take the form of a computer program product accessible from a computer-usable or computer-readable medium providing program code for use by or in connection with a computer or any instruction execution system. For the purposes of this description, a computer-usable or computer-readable medium can be any apparatus that can contain, store, communicate, propagate, or transport the program for use by or in connection with the instruction execution system, apparatus, or device.

The medium may be an electronic, magnetic, optical, electromagnetic, infrared, semiconductor system (or apparatus or device), or a propagation medium. Examples of a computer-readable medium include a semiconductor or solid state memory, magnetic tape, a removable computer diskette, a random access memory (RAM), a read-only memory (ROM), a rigid magnetic disk, and an optical disk. Current examples of optical disks include DVD, compact disk-read-only memory (CD-ROM), and compact disk-read/write (CD-R/W).

From FIG. 3, the ISS 405 receives inputs from one or more sensor sets (410, 420, 430). A sensor set as used herein may include a single sensor or be an arrangement of a plurality of sensors, none of which are required to be of the same or similar type or utility and none of which are required to not be of a same or similar type and utility. A sensor set, or grouping, may include or be determined in relation to one or more of the type of sensors, the type of application intended, the type of application the sensor is to be connected or in communication with, etc. It will be appreciated by those skilled in the art that the present invention is not constrained or limited to a particular arrangement of sensor in a specific manner to constitute a grouping herein.

For example in an embodiment, using FIG. 3 as an exemplar, sensor set 1 (410) includes a 3-axis accelerometer, 3 axis gyroscope, and a 3-axis magnetometer. Sensor set 2 (420) includes certain sensors exposed to the environment such as a pressure sensor, a microphone, a chemical sensor, a gas sensor, a humidity sensor, etc. Sensor set 3 (430) includes certain sensors being one or more of ambient light, proximity, touch, and audio-based sensors. In a further embodiment, each of the sets of sensors is connected to a dedicated processor, where the connected processor is a general purpose processor.

In yet a further embodiment, each of the sets of sensors is connected to a dedicated processor, where the connected processor is a specialized processor, such as that required, by example, for an audio processor to process audio input. In still another embodiment, each of the sets of sensors is arranged in relation to the processor to which it connects.

It will also be appreciated that each of the processors of the present invention can execute various sensor fusion algorithms in which the sensor fusion algorithms are algorithms that combine various sensor inputs to generate one or more of the orientation of the device or combined sensors data that may then be used for further processing or any other actions as appropriate such as determining orientation of the user.

Returning to FIG. 3, the sensor hub 450 provides for facilitating efficient communication among the sensors for improved high-level features. For example, in one or more embodiments, the sensor hub is capable of recognizing gestures and trigger sensors that are turned off/on or trigger processors. Similarly, the sensor hub is capable of performing intelligent sensor fusion in one or more aspects. For example, the present invention is capable of combining data from light, enabling proximity and motion sensors to thereby trigger resulting in the sending of data from a microphone to an audio processor (AP). Additionally, in one or more embodiments, the sensor hub is capable of processing sensor inputs and output signals that actuate haptic sensors (i.e., tactile feedback technology which takes advantage of the sense of touch by applying forces, vibrations, or motions to the user). Using the present invention, the output signals can be one or more of audio, vibration or light (LED).

From FIG. 3, the power management block 453 performs power management operations across all sensor sets, including external sensors 470. Using the present invention, the power management block is capable of turning off or turning on a sensor based on other sensor inputs or input from the application processor (AP). The power management block is further capable of putting the device or processors in a low power mode based on the one or more sensors. The power management block is further capable of applying a low power mode to one or more sensors based on one or more other sensors.

For example, when a gesture is recognized by a processor, the power management block is capable of turning on the microphone. In another example, when the ambient light sensor senses low light in an environment and the sensed low light situation is then combined with accelerometer measurements, the device may be set or otherwise configured for sleep mode.

From FIG. 3, the memories 452a-452d can store raw sensor data from sensors, including those of the external sensors. The motion data or processed data is also stored in the memory. It will be appreciated that the present invention is not limited to particular memory configurations or types such that memories 452a-452d as used herein can include single port or multiport SRAM, DRAM or FIFO, for instance. In other embodiments, a first memory can reside in ISS 405 outside sensor hub 450 in addition to memories 452a-452d to store any of sensor data, motion data and instructions. In yet other embodiments, a second memory can reside external to ISS 405 to store sensor data, motion data and instructions.

The controller block 454 of FIG. 3 includes control logic for the sensor hub 450. The controller block, also includes a bus master. The bus master, not pictured, manages the data storage from sensors and also provides for the storing of data from the processors.

In a further embodiment the sensor hub of the present invention is capable of receiving measurements from more than one sensor to determine the “context” of the user's actions. In the embodiment, the sensor hub is capable of then interpreting gestures or actions according to the context.

Context can be established in a variety of ways. In one example, location can establish the context. The context could be established based on the way a system is connected (GPS, local Wi-Fi etc.) of the device to be controlled are connected.

A state of the device to be controlled establishes the context. For example, if a device that includes the ISS has browser page open, this could for example mean a context to enable “air-mouse” type functionality on a wearable device is established. This state could be as simple as the device being turned on.

In other aspects, a system and method in accordance with the present invention can be implemented in varying contexts and situations. For instance, in a preferred embodiment, a location defined the context for the operation of the ISS of the present invention. In such a situation, the implementation could be based on inertial sensors providing location information or the way in which the system is connected (such as with localized WI-FI or via another connection method) where all the devices to be controlled are connected similarly, irrespective of the WI-FI source, etc.

Still, in other aspects, an implementation could be based on the state of the device to be controlled as defining the context. For example, in an implementation involving a television having a browser page open, a context to enable “air-mouse” type functionality on the wearable device could be established. In such an implementation, the state could simply be the device being turned ON or OFF.

Still, in other aspects, an implementation could be based on time as defining the context. For example, in an implementation involving a determination as to whether it is day or night to enable a light on/off functionality.

Further, in other aspects, an implementation could be based on proximity as defining the context. For example, in an implementation an ISS providing information about proximity to a device could be used as context.

Additionally, in other aspects, an implementation could be based on a picture of the device to be controlled as defining the context. For example, in an implementation of such a picture of the device could be a used as a context such as in the situation where the wearable device takes the form of computer-based glasses for instance.

Still, in other aspects, an implementation could be based on a device being turned ON or OFF as defining the context. For example, in an implementation involving a device turning ON (one sensor), such could further be associated with a proximity to the device (another sensor).

Still, in other aspects, an implementation could be based on a device being activated by another independent act as defining the context. For example, in an implementation involving a phone ringing, as such is triggered by a calling in to a line from the act of another, such could further be associated with lowering volumes or turning off those associated remote devices that are active at the time of the phone ringing.

Further, in other aspects, an implementation could be based on being able to access a device's actuation as defining the context. For example, in an implementation involving a garage door, even in the event where a car within the garage is being stolen, the thief is unable to open the garage door absent having control over a device that includes an ISS which enables the door to open or close.

Further, in other aspects, an implementation could be based on a user's situation as defining the context. For example, in an implementation involving a user sleeping, under such a context, the sensors of the ISS could establish Turn-off/Turn-on features on one or more remote devices (e.g., auto alarm the house, control thermostat, CO-Alarm, smoke detector, etc.).

Still further, in other aspects, an implementation could be based on a context of a social gathering at a predetermined location. For example, in an implementation involving a social event having a series of predetermined timed events where each event has multiple remote devices engaged to be activated to perform a function (e.g., streamers release, music, lights, microphone, etc.), each remote device is configured to be active only during pre-set periods and each device is also configured to recognize and receive specific commands from gestures or movements from a device that includes the ISS. In such a situation, a user can control certain of the remote device independent from another and other dependent with one another, without manually resetting or engaging others at additional costs to operate the event. In such an operation,

By utilizing different types of sensors more information can be provided to obtain the proper context. Hence, depending upon the situation there may be different levels of importance for different types of situations. For example, if there is a meeting, that has a person has remote access to the primary sensors may be motion sensors that allow the user to know a person has entered the room that information may engage a video camera and a microphone at the remote location that allows the user to see and communicate with who has entered. In another example, additional sensors may be used to provide information about which room is being utilized for the meeting as well as the identity of all the attendees to provide more context. The above description is by way of example only and one of ordinary skill in the art recognizes that any or any combination of sensors can provide context information and generally the more different types of sensors that are available will improve the context for a user. The sensors in the ISS along with the algorithm in the memory can detect basic units such as a velocity, acceleration, gravity, elevation, environmental motion/vibrations, background noise, audio signature, detecting keywords, images, video, motion gestures, image gesture, ambient light, body temperature, ambient temperature, humidity, rotation, orientation, heading, ambient pressure, air quality, and flat tire detection. The air quality can be the amount of oxygen (O2), carbon dioxide (Co2) or a particle count.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A device, comprising:
a plurality of sensors;
a plurality of processors, wherein each processor of the plurality of processors is coupled to a respective sensor of the plurality of sensors; and
a sensor hub coupled to the plurality of sensors, wherein the sensor hub receives sensor data from the plurality of sensors, and wherein the plurality of sensors and the sensor hub are located on two substrates.

2. The device of claim 1, wherein the two substrates are a complementary metal oxide substrate and a microelectromechanical system substrate.

3. The device of claim 2, wherein the CMOS substrate and the MEMS substrate are stacked vertically atop one another and electrically connected to one another to form a single semiconductor chip.

4. The device of claim 1, wherein the plurality of sensors are formed only on the MEMS substrate and electronic circuits that convert analog signals to digital signals are formed on the CMOS substrate.

5. The device of claim 1, wherein the plurality of sensors are configured to determine a sensed activity, wherein the sensed activity comprises at least one of flying, reading, eating, driving or working at a computer.

6. The device of claim 1, wherein the plurality of sensors are configured to determine a sensed location, wherein the sensed location comprises a moving vehicle.

7. The device of claim 1, wherein the plurality of sensors are configured to determine a sensed location, wherein the sensed location comprises a store.

8. The device of claim 1, wherein the plurality of sensors are configured to determine a sensed location, wherein the sensed location comprises a home or workplace.

9. The device of claim 1, wherein the two substrates are a complementary metal oxide substrate and a microelectromechanical system substrate and the two substrates are attached to one another via wafer bonding that provides electrical connections and hermetically seals the plurality of sensors formed on the MEMS substrate.

10. The device of claim 1, wherein the plurality of sensors comprise a sensor that detects at least one of velocity, acceleration, gravity, elevation, environmental motion/vibrations, background noise, audio signature, detecting keywords, images, motion gestures, image gesture, ambient light, body temperature, ambient temperature, humidity, rotation, orientation, heading, ambient pressure, air quality or tire pressure.

11. The device of claim 10, wherein the air quality comprises at least one of an amount of oxygen (O2), an amount of carbon dioxide (Co2) or a particle count.

12. The device of claim 1, wherein at least one of the plurality of processors comprises an audio processor, an image processor, a motion processor, a touch processor, a location processor, a wireless processor, a radio processor, a graphics processor, a power management processor, an environmental processor, an activity processor or a microcontroller unit (MCU).

13. A device, comprising:
a plurality of sensors;
a plurality of processors, wherein each processor of the plurality of processors is coupled to a respective sensor of the plurality of sensors; and
a sensor hub coupled to the plurality of sensors, wherein the sensor hub receives sensor data from the plurality of sensors.

14. The device of claim 13, wherein the plurality of sensors are configured to determine a sensed location, wherein the sensed location comprises a moving vehicle or a store.

15. A device, comprising:
a plurality of sensors;
a plurality of processors coupled to the plurality of sensors; and
a sensor hub coupled to the plurality of sensors, wherein the sensor hub receives sensor data from the plurality of sensors, and wherein the plurality of sensors and the sensor hub are located on a complementary metal oxide substrate and a microelectromechanical system substrate.
